(19) United States
(12) Patent Application Publication
(10) Pub. No.: US 2021/0380268 A1
(43) Pub. Date: Dec. 9, 2021

(54) POWER SUPPLY FOR ELECTRIC AND/OR ELECTRONIC COMPONENTS

(71) Applicant: Rolls-Royce Deutschland Ltd & Co KG, Blankenfelde-Mahlow (DE)

(72) Inventors: Swen Ruppert, Möhrendorf (DE); Uwe Waltrich, Erlangen (DE)

(21) Appl. No.: 17/285,974

(22) PCT Filed: Oct. 11, 2019
(86) PCT No.: PCT/EP2019/077580

§ 371 Date: Apr. 16, 2021

(30) Foreign Application Priority Data
Oct. 17, 2018 (DE) 10 2018 217 780.5

(51) Int. Cl. B64D 33/08; H05K 7/20; B64D 27/24

(52) U.S. Cl. CPC B64D 33/08; B64D 27/24; H05K 7/20854; H05K 7/209

(57) ABSTRACT

A device is provided for supplying electric power to electric and/electronic components of a power converter. The device includes at least one power module, at least one capacitor, at least one heat sink between the power module and the capacitor, a first DC conductor element having a first potential, and at least one additional, second DC conductor element having a second potential. The first and second DC conductor elements are configured to supply electric power to the power module and the capacitor. The first and second DC conductor elements extend coaxially to each other by the heat sink. The disclosure also relates to a power converter and an aircraft.

The present patent document is a § 371 nationalization of PCT Application Serial No. PCT/EP2019/077580, filed Oct. 11, 2019, designating the United States, which is hereby incorporated by reference, and this patent document also claims the benefit of German Patent Application No. 10 2018 217 780.5, filed Oct. 17, 2018, which is also hereby incorporated by reference.

### TECHNICAL FIELD

The present disclosure relates to a device for supplying electric power to electric and/or electronic components of a power converter. The disclosure also relates to a power converter and to an aircraft with such a device. The disclosure may be used, in particular, in electric or hybrid-electric aircraft propulsion in aviation.

### BACKGROUND

Power modules are screwed onto heat sinks (e.g., liquid or air coolers) for cooling. Many power converter topologies require an intermediate circuit capacitor which must be electrically connected to a power module with as low an inductance and resistance as possible. As a first approximation, the necessary capacitance of the intermediate circuit is proportional to the required volume and weight of the capacitor. The permissible temperature inside the capacitor may limit optimal utilization of the output stage. The losses in the capacitor must therefore be dissipated through a good thermal connection. Cooling via the electric connection surfaces of the capacitor is most effective with film capacitors.

From products available on the market, the applicant is aware of thermally connecting the capacitor to the still “free” underside of the heat sink in order to have a construction which is as compact and light as possible. The connection is mostly made via screw connections and a pressing mechanism. The required low-inductance connection is routed and contact-connected via laminated busbars (electrically insulated, thermally conductive) with appropriate bends to the power module on the opposite side of the heat sink.

This has the disadvantage that the clamping mechanism (frame, screws, etc.) and the bent copper busbar are weight-intensive. In addition, the minimum length of the connection between the intermediate circuit capacitor and the power module is determined by the heat sink geometry. This length is directly proportional to the commutation inductance and is therefore to be regarded as critical. In addition, the tolerances make the welding processes more difficult. The welding in turn leads to a rigid connection and a thermomechanical load on the connection and the mostly rigid ceramic circuit carrier of the power module. Finally, pressing the busbar contacts down onto the module requires additional mechanical effort.

From products available on the market, the applicant is also aware of solutions in which the electric contact-connection of the side of the capacitor facing away from the heat sink takes on the tasks of electric conduction and thermal heat dissipation to the heat sink.

### SUMMARY AND DESCRIPTION

The object of the disclosure is to specify a solution for improved supply of electric power to electric and/or electronic components, which may be used, in particular, in hybrid-electric drives in aviation.

According to the disclosure, the stated object is achieved with the device for supplying electric power to electric and/or electronic components of a power converter, the power converter, and the aircraft as described herein.

The scope of the present disclosure is defined solely by the appended claims and is not affected to any degree by the statements within this summary. The present embodiments may obviate one or more of the drawbacks or limitations in the related art.

According to the disclosure, a capacitor, (e.g., an intermediate circuit capacitor), is electrically contact-connected to a power module and thermally contact-connected to a heat sink by DC conductor elements running in a manner arranged coaxially to one another.

A device is provided for supplying electric power to electric and/or electronic components of a power converter, having at least one power module, at least one capacitor, at least one heat sink arranged between the power module and the capacitor, a first DC conductor element with a first potential and at least one further, second DC conductor element with a second potential. The first and second DC conductor elements are configured to supply the power module and the capacitor with electric power. In other words, the first and second DC conductor elements are electrically connected to the power module and the capacitor. The first and second DC conductor elements run through the heat sink in a manner arranged coaxially to one another. The DC conductor elements are, for example, in the form of a bushing through the heat sink. A cooling medium may flow around and/or through the heat sink.

The disclosure offers the advantage of a weight-saving thermal, electric, and mechanical connection through the omission of a weight-intensive and rigid busbar system. In addition, the disclosure offers the advantage of a very low-inductance connection through the DC conductor elements running coaxially to one another through the heat sink.

In a further configuration, the capacitor may be an intermediate circuit capacitor or a flying cap capacitor, which may be implemented as a film capacitor, for example.

In a further embodiment, at least in the region running in the heat sink, the first DC conductor element is in the form of a pin and the second DC conductor element is in the form of a sleeve.

In a development, the pin may be in the form of a screw which may be screwed into a thread in such a way that the capacitor and the power module may be pressed onto the heat sink.

The intermediate circuit capacitor screw connection offers the advantage that it multifunctionally serves as a thermal, electric, and mechanical contact-connection between the capacitor and the heat sink. The screw connection constitutes a thermally optimized connection of the intermediate circuit capacitor by virtue of the two-sided cooling (second heat path through screw connection).

In a further embodiment, the thread is formed in a screw nut in the capacitor or in the heat sink. This may be effected, for example, by a threaded insert.

In a further embodiment, the connection between the power module and the heat sink may be made with a solder layer instead of a pin. The heat sink may have DC capacitor connection surfaces on that side of the power module onto which the power module is soldered. Power modules without base plates may have a coaxial pattern of the heat-sink-side DC capacitor connection surfaces on the underside. As a result, the soldering of the substrate onto the heat sink may also be used for electric contact-connection of the power module, which further reduces the commutation inductance. There may also be an insulation potting compound between the solder layer.

In a further embodiment, the power module may be formed from multilayer substrates. This may include direct bonded copper (DCB), active metal braze (AMB), low-temperature co-fired ceramic (LTCC), and a printed circuit board.

In a development, the device has a plate, (e.g., a spring plate), which is arranged on the capacitor on the side facing away from the heat sink and is pressed against the capacitor by the screw. This provides the advantage of cooling the capacitor on both sides. Depending on the arrangement of the contact points of the capacitor, the plate may be locally electrically conductive or insulating.

In a development, the heat sink is formed from an electrically insulating ceramic material. Alternatively, the passages on the capacitor may be electrically insulated. Electrically insulated passages may be formed, for example, with hollow cylinders.

A power converter is also disclosed, the power converter having a device as described herein.

In a development, the power converter may be a converter.

In addition, an aircraft is disclosed herein. The aircraft includes a device and a power converter, for example, for an electric or hybrid-electric aircraft propulsion system.

In a development, the aircraft may be an airplane.

In a development, the aircraft has an electric motor supplied with electric power by the converter and a propeller that may be set in rotation by the electric motor.

Extensions with additional DC conductor elements, power modules, heat sinks, and/or capacitors are possible.

An aircraft is understood to refer to any type of airborne device or apparatus of locomotion or transport, be it manned or unmanned.

### BRIEF DESCRIPTION OF THE DRAWINGS

The special features and advantages of the disclosure become apparent from the following explanations of a plurality of exemplary embodiments on the basis of schematic drawings, in which:

FIG. 1 depicts a cross section of a coaxial DC capacitor connection to the power module and heat sink, according to an embodiment.

FIG. 2 depicts a cross section of a coaxial DC capacitor connection to the heat sink with a soldered power module, according to an embodiment.

FIG. 3 depicts a plan view of a coaxial DC capacitor connection, according to an embodiment.

FIG. 4 depicts a plan view of another coaxial DC capacitor connection, according to an embodiment.

FIG. 5 depicts a block diagram of a device for supplying electric power to electric and/or electronic components of a power converter, according to an embodiment.

FIG. 6 depicts a view of an airplane, according to an embodiment.

### DETAILED DESCRIPTION

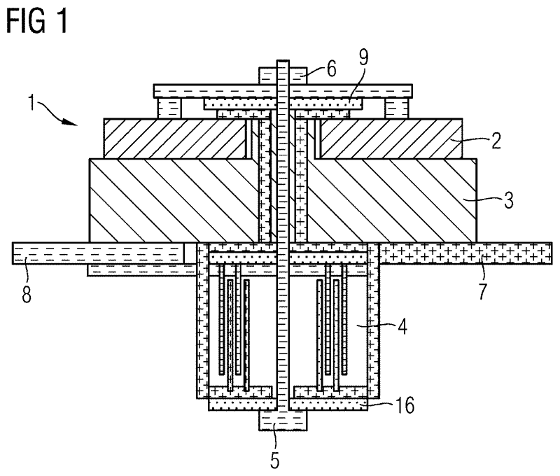

FIG. 1 depicts a schematic cross section of a coaxial DC capacitor connection to power electronics and a cooling system. The power electronics (or power module 2), a heat sink 3, through which a cooling medium (not illustrated) may flow, and a capacitor 4, (e.g., an intermediate circuit capacitor), (which may be implemented as a film capacitor), may be seen.

A coaxial DC capacitor connection, (constructed from two DC conductor elements 7, 8), runs coaxially to the capacitor 4. The first DC conductor element 7 has a first potential which may be implemented, for example, as a DC plated-through hole at a positive potential. The second DC conductor element 8 has a second potential and may be in the form of a DC plated-through hole at a negative potential. At least in the region of the heat sink 3, the second DC conductor element 8 runs coaxially inside the first DC conductor element 7. In the example, the first DC conductor element 7 is partially in the form of a pin, (e.g., a screw 5). By being fastened in a thread 12, (e.g., the thread 12 of a screw nut 6), the pin presses the capacitor 4 onto the heat sink 3. A plate 16, (e.g., a spring plate), is fitted between the capacitor 4 and the head of the screw 5 and presses the capacitor 4 onto the heat sink 3 by way of the screw 5. The pressing produces an electric and thermal contact-connection of the side facing the heat sink 3. By using a thermally (highly) conductive plate 16, (e.g., made of a mechanically stable ceramic (Si₃N₄, Al₂O₃)), an additional thermal path is created via the screw 5 from the side of the capacitor 4 facing away from the heat sink 3 to the heat sink 3. As a result, the capacitor 4 is cooled on both sides.

Alternatively, the screw 5 may be fastened by a thread 12 in the capacitor 4, here configured as a threaded insert. In the example shown, the head of the screw 5 is on the side of the capacitor 4 and the screw nut 6 is on the side of the power module 2. An alternative possibility is to position the head of the screw 5 on the side of the power module 2 and the screw nut 6 on the side of the capacitor 4.

Electric insulating layers 9 are located between the first DC conductor element 7 and the second DC conductor element 8. The heat sink 3 may be formed from electrically insulating ceramic or alternatively from metal with insulation for the first and second DC conductor elements 7, 8.

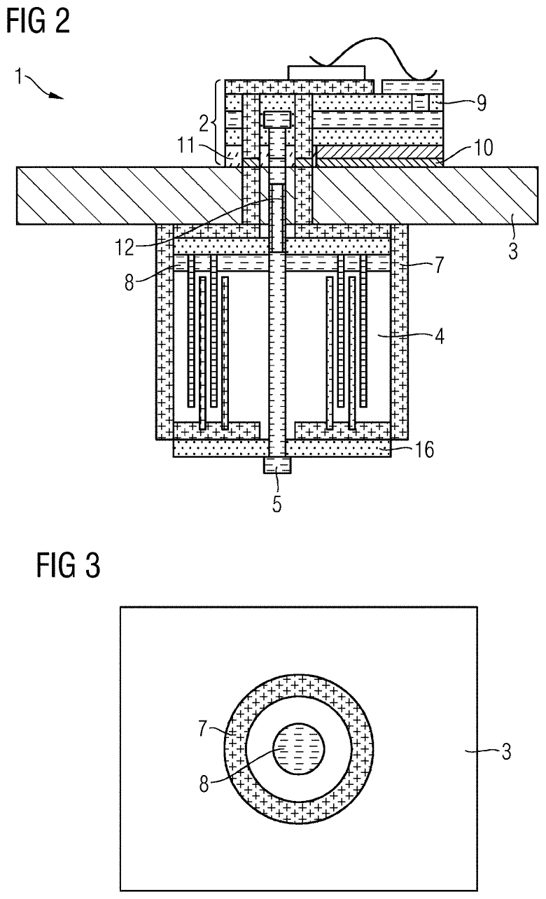

FIG. 2 depicts an alternative form of the embodiment to FIG. 1. The alternative, also shown in cross section, shows a version in which the power module 2 is soldered onto the heat sink 3 with a solder layer 10. The heat sink 3 has DC capacitor connection surfaces on that side of the power module 2 onto which the power module 2 is soldered. Power modules 2 without base plates and with multilayer substrates may have a coaxial pattern of the heat-sink-side DC capacitor connection surfaces on the underside. As a result, the soldering of the substrate onto the heat sink 3 may also be used for electric contact-connection of the power module 2, which further reduces the commutation inductance. The advantage of this variant is that the contact point from the power module 2 to the heat sink 3 is thus optimally cooled with an ohmic contact resistance. The losses of the screw contacts may be an additional heat source that would heat up the capacitor 4. In addition, increased temperature changes at the contact point lead to a reduction in the service life. This also improves this.

In addition, the power module 2 is illustrated in greater detail than in FIG. 1. The multilayer substrate made of DCB, AMB, LTCC, and a printed circuit board may be seen. An insulation potting compound 11 is located on the solder layer 10 (for example, as underfill material which may be applied through feed lines specially provided for this purpose in the substrate layout or connected to the edge of a circuit carrier). As in FIG. 2, the capacitor has a first DC conductor element 7 and a second DC conductor element 8. The first DC conductor element 7 has a first potential which may be implemented, for example, as a DC plated-through hole at a positive potential. The second DC conductor element 8 has a second potential and may be in the form of a DC plated-through hole at a negative potential. Electric insulating layers 9 are located between the positive first DC connections 7 and the negative DC plated-through holes 8. In this embodiment, the screw 5 only connects the capacitor 4 and the heat sink 3. The screw 5 runs through the entire capacitor 4 and is fastened in an internal thread 12 which sits in the capacitor 4. In addition to the mechanical connection, this also creates an electric plated-through hole.

FIG. 3 depicts a sectional view through the heat sink 3 of a coaxial DC capacitor connection with a first DC conductor element 7 and a second DC conductor element 8. The first DC conductor element 7 has a first potential which may be implemented, for example, as a DC plated-through hole at a positive potential. The second DC conductor element 8 has a second potential and may be in the form of a DC plated-through hole at a negative potential. The second DC conductor element 8 located in the interior runs coaxially to the first DC conductor element 7.

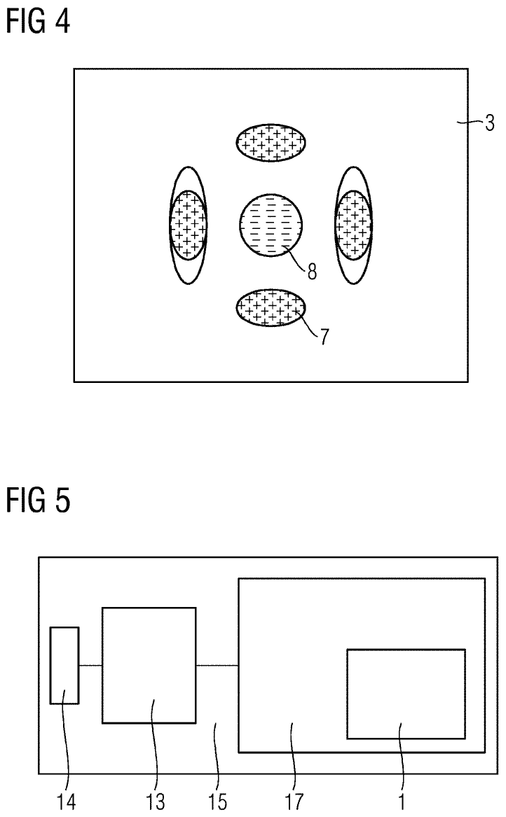

FIG. 4 depicts a sectional view through the heat sink 3 of a coaxial DC capacitor connection with four first DC conductor elements 7 and a second DC conductor element 8 as an alternative form of embodiment to FIG. 3. The first DC conductor elements 7 have a first potential which may be implemented, for example, as a DC plated-through hole at a positive potential. The second DC conductor element 8 has a second potential and may be in the form of a DC plated-through hole at a negative potential. The second DC conductor element 8 runs coaxially to the first DC conductor elements 7 arranged around it.

In FIGS. 1 to 4, parts that are at a positive potential are provided with plus signs, while parts with a negative potential have minus signs.

FIG. 5 depicts a block diagram of a device 1 for supplying electric power to electric and/or electronic components of a power converter 12, with an operatively connected electric motor 13 and a propeller 14 of an airplane 15. The power converter 12 may be a converter.

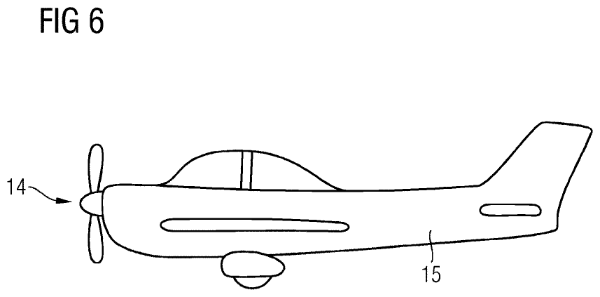

FIG. 6 depicts a view of an electric or hybrid-electric airplane 15, as an example of an aircraft, with a non-visible power converter 12 that supplies the non-visible electric motor 13 with electric power. The electric motor 13 sets a propeller 14 in rotation.

In addition to the application presented, the added value also exists in other applications. There are many power converter applications in which a high clock rate is required and thus a low-inductance connection is necessary. This may apply to high speeds or high numbers of poles in the electric machine.

Although the disclosure has been illustrated and described more specifically in detail by the exemplary embodiments, the disclosure is not restricted by the disclosed examples and other variations may be derived therefrom by a person skilled in the art without departing from the scope of protection of the disclosure.

It is to be understood that the elements and features recited in the appended claims may be combined in different ways to produce new claims that likewise fall within the scope of the present disclosure. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

1. A device for supplying electric power to electric and/or electronic components of a power converter, the device comprising:
a power module;
a capacitor;
a heat sink arranged between the power module and the capacitor;
a first DC conductor element with a first potential; and
a second DC conductor element with a second potential,
wherein the first DC conductor element and the second DC conductor element are electrically connected to the power module and the capacitor, and
wherein the first DC conductor element and the second DC conductor element run through the heat sink in a manner arranged coaxially to one another.

2. The device of claim 1, wherein the capacitor is an intermediate circuit capacitor or a flying cap capacitor.

3. The device of claim 1, wherein at least in a region running in the heat sink, the first DC conductor element is in a form of a pin, and the second DC conductor element is in a form of a sleeve.

4. The device of claim 3, wherein the pin is a screw configured to be screwed into a thread such that the capacitor and the power module are configured to be pressed onto the heat sink.

5. The device of claim 4, wherein the thread is in a screw nut in the capacitor or in the heat sink.

6. The device of claim 4, further comprising:
a plate arranged on the capacitor on a side facing away from the heat sink and pressed against the capacitor by the screw.

7. The device of claim 1, wherein the heat sink comprises an electrically insulating ceramic material.

8. A power converter comprising:
a device for supplying electric power to electric and/or electronic components of the power converter, the device comprising:
a power module;
a capacitor;
a heat sink arranged between the power module and the capacitor;
a first DC conductor element with a first potential; and
a second DC conductor element with a second potential,
wherein the first DC conductor element and the second DC conductor element are electrically connected to the power module and the capacitor, and
wherein the first DC conductor element and the second DC conductor element run through the heat sink in a manner arranged coaxially to one another.

9. The power converter of claim 8, wherein the power converter is a converter.

10. An aircraft comprising:
a power converter for an electric or hybrid-electric aircraft propulsion system,
wherein the power converter comprises a device for supplying electric power to electric and/or electronic components of the power converter,
wherein the device of the power converter comprises:
a power module;
a capacitor;
a heat sink arranged between the power module and the capacitor;
a first DC conductor element with a first potential; and
a second DC conductor element with a second potential,
wherein the first DC conductor element and the second DC conductor element are electrically connected to the power module and the capacitor, and
wherein the first DC conductor element and the second DC conductor element run through the heat sink in a manner arranged coaxially to one another.

11. The aircraft of claim 10, wherein the aircraft is an airplane.

12. The aircraft of claim 11, further comprising:
an electric motor supplied with electric power by the power converter; and
a propeller configured to be set in rotation by the electric motor.

13. The aircraft of claim 10, further comprising:
an electric motor supplied with electric power by the power converter; and
a propeller configured to be set in rotation by the electric motor.

14. The device of claim 2, wherein at least in a region running in the heat sink, the first DC conductor element is in a form of a pin, and the second DC conductor element is in a form of a sleeve.

15. The device of claim 14, wherein the pin is a screw configured to be screwed into a thread such that the capacitor and the power module are configured to be pressed onto the heat sink.

16. The device of claim 15, wherein the thread is in a screw nut in the capacitor or in the heat sink.

17. The device of claim 15, further comprising:
a plate arranged on the capacitor on a side facing away from the heat sink and pressed against the capacitor by the screw.
